(19) United States
(12) Patent Application Publication
(10) Pub. No.: US 2019/0187307 A1
(43) Pub. Date: Jun. 20, 2019

(54) HIGH EFFICIENCY 3D NANOSTRUCTURED NEUTRON DETECTORS

(71) Applicant: United States Department of Energy, Washington, DC (US)

(72) Inventors: Young Soo Ham, San Ramon, CA (US); Sangil Kim, Wilmette, IL (US)

(21) Appl. No.: 16/219,027

(22) Filed: Dec. 13, 2018

Related U.S. Application Data
(60) Provisional application No. 62/598,554, filed on Dec. 14, 2017.

(51) Int. Cl. G01T 3/08; H01L 29/06

(52) U.S. Cl. CPC G01T 3/08; H01L 29/0669

(57) ABSTRACT

Exemplary embodiments of the present invention comprise a high efficiency 3D nanostructured neutron detector. The neutron detector comprises a primary and secondary substrate, each substrate comprising an external and internal surface area, wherein one of the respective substrates comprises an n-type semiconductor material and the other substrate comprises a p-type semiconductor material. Disposed between the primary and secondary substrates is a composite structure consisting of a predetermined neutron converting material and a predetermined neutron detecting material, wherein one of the composite materials is fabricated into a nanostructure in the configuration of a stack of nanosheets, a 3D nanowire network, or as 3D nano-trees, and a pair of electrodes, wherein one electrode is disposed on the respective external surface areas of the primary and secondary substrates.

### FIELD OF THE INVENTION

Recent shortages of Helium-3 (3He) have posed a great threat to national security and research programs in the United States and around the world. The present invention describes an innovative, highly efficient neutron sensing device that is comprised of nanostructured neutron converter or semiconductor neutron detection materials. The nanostructured neutron converter and semiconductor composite devices of the present invention provide high neutron detection efficiency that is compatible to that of 3He detectors and significantly higher than other types of current neutron detectors. In addition, the employment of organic semiconductor matrix materials within embodiments of the present invention can be utilized to fabricate thin and flexible neutron sensors, wherein such devices can he directly embedded within clothing material.

### DESCRIPTION OF THE BACKGROUND

Neutron detectors with improved detection efficiency are highly sought after for a range of applications including: fissile materials detection, neutron therapy, medical imaging, the study of materials sciences, protein structures probing, and oil exploration. In particular, radiation detection services are a critical aspect of the monitoring of people and cargos for smuggled nuclear materials. Radiation detection is incorporated into the designing of nuclear power plants to assist in the monitoring of power levels and also ensure safe operations.

Among various types of neutron detection materials 3He has been widely and extensively used for thermal neutron detection systems, but a recent shortage of 3He was serious enough to beget a hearing in the US Congress to examine the causes and consequences of the 3He supply crisis. Recently, the cost of 3He per liter increased from approximately $200 to more than $2,000 in the span of one year causing serious impact on national security programs as well as on industry and research communities. In its September 2011 report the Government Accounting Office (GAO) identified three available alternative neutron detector technologies: B10 lined proportional detectors, BF3 proportional detectors, and Li6 scintillators. However, each of these detector technologies suffer from one or more deficiencies such as toxicity, lack of high detection efficiency, low gamma radiation discrimination, or lack of counting capability at high neutron flux.

The development of new neutron detector technologies that have broader applications for research and industry as well as for security applications is urgently needed. Currently the most wide spread approach for obtaining a solid-state neutron detector is to coat boron containing neutron-to-alpha particle conversion material onto a semiconductor (comprised from materials such as on Si or GaAs) or to construct a boron based semiconductor detector.

The working principle is that boron-10 (10B) isotopes have a capture cross-section of 3840b for thermal neutrons (with 0.025 eV energy), which is of an order of magnitude much larger than those of most isotopes. However, current solid-sate detectors (including boron based neutron conversion materials) suffer from inherently low conversion efficiency, poor resolution, non-uniform electric field, polarization, moderate to poor field ability, inconvenient geometries, low absolute efficiency, and a lack of directional information.

Microstructure semiconductor neutron detectors (typically backfilled with neutron converter materials) have been studied as high-efficiency thermal neutron detectors. The basic configuration of these detectors comprise a common pn junction diode that is microstructured with an etched pattern and backfilled with neutron converter materials such as Boron or LiF. Such detector devices are compact, easily produced in mass-quantity and have low power requirements. Further, the devices are far superior to common thin-film planar neutron detectors, for which the thickness of the neutron conversion layer must be large enough but at the same time it must be thin enough to permit the alpha particles to reach a semiconductor layer and produce electron hole pair.

### SUMMARY OF THE INVENTION

The shortcomings of the prior art are overcome and additional advantages are provided through the provision of a radiation sensor containing nanostructured materials for the detection of neutrons with high detection efficiency. Such neutron detectors can be applied to build neutron measurement systems to fight against nuclear terrorism, nuclear proliferation and to promote research programs.

An embodiment of the present invention comprises a high efficiency 3D nanostructured neutron detector, wherein the neutron detector comprises a primary and secondary substrate. Each substrate comprises an external and internal surface area, wherein one of the respective substrates comprises an n-type semiconductor material and the other substrate comprises a p-type semiconductor material. Disposed between the primary and secondary substrates is a composite structure consisting of a predetermined neutron converting material and a predetermined neutron detecting material. Further, a pair of electrodes is comprised, wherein a respective electrode is disposed on the external surface area of the primary and secondary substrates. One of the materials of the composite structure is fabricated into a nanostructure in the configuration of a stack of nanosheets, a 3D nanowire network, or as 3D nano-trees.

Within the exemplary embodiment of the present invention the nanostructure of the embodiments is fabricated from nanotubes or nanowires. The structural parameters of the nanostructure are determined in order to control the fabrication dimensions of the nanostructured materials, and the nanostructures can be fabricated by micro-architectured pattern growth directly on a semiconductor substrate.

Within another exemplary embodiments of the present invention the 3D nanostructure neutron detector is constructed of a fabricated nanostructure comprising a predetermined neutron converting material. The nanostructure of the composite therein comprises a plurality of neutron converting material nanosheets, 3D nanowire networks, or 3D nano-trees that have been dispersed within a structure comprised of a neutron detecting material.

Within a further exemplary embodiment of the present invention the 3D nanostructure neutron detector is fabricated from nanostructures comprising a predetermined neutron detecting material. The nanostructure of the composite therein comprises a plurality of neutron detecting material 3D nanowires or 3D nano-trees that have been dispersed within a structure comprised of a neutron converting material.

Within an additional exemplary embodiment of the present invention the 3D nanostructure neutron detector is constructed of a fabricated nanostructure comprising a predetermined neutron conducting material. The nanostructure of the composite therein comprises a plurality of neutron converting nanowires, 3D nano-trees, or 3D nanowire networks dispersed within a structure comprised of a flexible organic matrix material.

Within a yet further exemplary embodiment of the present invention a method for the fabrication of a high efficiency 3D nanostructured neutron detector is presented. The method comprising the steps of: fabricating a primary and secondary substrate, each comprising an outer and inner surface area, wherein one of the respective substrates comprises an n-type semiconductor material and the other substrate comprises a p-type semiconductor material; fabricating upon the inner surface area of the primary substrate a composite structure, the composite structure consisting of a predetermined neutron converting material and a predetermined neutron detecting material wherein one of the composite materials is fabricated into a nanostructure, the nanostructure being fabricated into a nanostructure array in the configuration of a stack of nanosheets, a 3D nanowire network, or as 3D nano-trees; depositing the inner surface area of the secondary semiconducting substrate upon an exposed upper surface area of the composite structure; and forming a conductive layer upon each substrate by depositing an electrode onto the exposed outer surface areas of the primary and secondary semiconducting substrates.

Additional features and advantages are realized through the techniques of the present invention. Other embodiments and aspects of the invention are described in detail herein and are considered a part of the claimed invention. For a better understanding of the invention with advantages and features, refer to the description and to the drawings.

### BRIEF DESCRIPTION OF THE DRAWINGS

The subject matter that is regarded as the invention is particularly pointed out and distinctly claimed in the claims at the conclusion of the specification. The foregoing and other objects, features, and advantages of the invention are apparent from the following detailed description taken in conjunction with the accompanying drawings in which:

FIG. 1a is an illustration of a 3D neutron detector comprising a layered neutron converting nanoflake/sheet structure and semiconductor material composite.

FIG. 1b is an illustration of a 3D neutron detector comprising a layered semiconductor nanoflake/sheet structure and neutron converting material composite.

FIG. 2a is an illustration of a 3D neutron detector comprising a 3D nanowire network fabricated from neutron converting materials and semiconductor material composite.

FIG. 2b is an illustration of a 3D neutron detector comprising a 3D nanowire network fabricated from a semiconductor material and neutron converting material composite.

FIG. 3a is an illustration of a 3D neutron detector comprising a 3D nano-tree system fabricated from neutron converting materials and semiconductor material composite.

FIG. 3b is an illustration of a 3D neutron detector comprising a 3D nano-tree system fabricated from semiconductor materials and neutron converting material composite.

FIG. 4a is an illustration of a 3D neutron detector comprising a nano-tree system fabricated from a neutron converting material situated within a flexible organic polymer matrix.

FIG. 4b is an illustration of a 3D neutron detector comprising a nanowire network fabricated from a neutron converting material situated within a flexible organic polymer matrix.

FIG. 4c is an illustration of a 3D neutron detector comprising a 1D nanowire system fabricated from a neutron converting material situated within a flexible organic polymer matrix.

The detailed description explains the preferred embodiments of the invention, together with advantages and features, by way of example with reference to the drawings.

### DETAILED DESCRIPTION OF THE INVENTION

One or more exemplary embodiments of the invention are described below in detail. The disclosed embodiments are intended to be illustrative only since numerous modifications and variations therein will be apparent to those of ordinary skill in the art. In reference to the drawings, like numbers will indicate like parts continuously throughout the views. Herein, the use of the terms first, second, etc., do not denote any order or importance, but rather the terms first, second, etc., are used to distinguish one element from another. Furthermore, the use of the terms a, an, etc., do not denote a limitation of quantity, but rather denote the presence of at least one of a referenced item.

The primary focus of this invention is the development of a radiation sensor that is efficient, reliable, cost effective, and does not require high energy levels for neutron detection. As such, the device is comprised of a composite segment that is fabricated from component materials comprising neutron converter materials (e.g. boron or LiF), and semiconductor neutron detector materials (e.g. Si or GaAs, Within the exemplary embodiments of the present invention one of the component materials is selected to serve as a nanostructure and the other to serve as the matrix within which the nanostructure will reside. Further, nanostructured materials can be fabricated as stacked nanoflakes or nanosheets, 3D nanowire networks, or 3D nano-tree structures. Various neutron converter materials can be utilized for nanostructure device or matrix fabrication within the exemplary embodiments of the present invention such as LiF, boron, boron nitride, boron carbide, and any combination of the materials such as BxCyNz etc.

The solid state thermal neutron detector of the present invention is a 3D p-i-n diode array comprising a nanostructure (nanoflake/sheet, nanowire network, nano-tree structure), wherein the nanostructure can either be fabricated from a neutron converter material or a semiconductor neutron detector material. In the event that a thermal neutron interacts with the neutron converting material of the diode array, energetic ions in the form of an alpha particle (α) and a lithium ion (⁷Li) are produced. The energetic ions will lose energy over their random paths of travel inside of the neutron detector. When the energy of these ions is deposited into the neutron detecting semiconducting material of the detector electron-hole pairs will be generated and subsequently collected within the diode, thus showing the presence of a neutron interaction event.

To fabricate neutron detection devices with high detection efficiency the structural parameters of the detection devices (i.e., the dimensions of the nanostructured materials, the spacing between nanowires or nanoflakes/sheets, etc.) has to be controlled by predetermining the synthesis and fabrication conditions that are necessitated in order to achieve desired structural parameters. In further exemplary embodiments of the present invention micro-architectured growth of nanotubes or nanowires can be performed directly on a semiconductor substrate so as to provide dimensional control of the fabrication of a device from nano to micro scales. In additional exemplary embodiments electrically conductive materials (e.g., boron carbide) are used to detect neutrons or byproduct particles directly without the use of semiconducting detector materials.

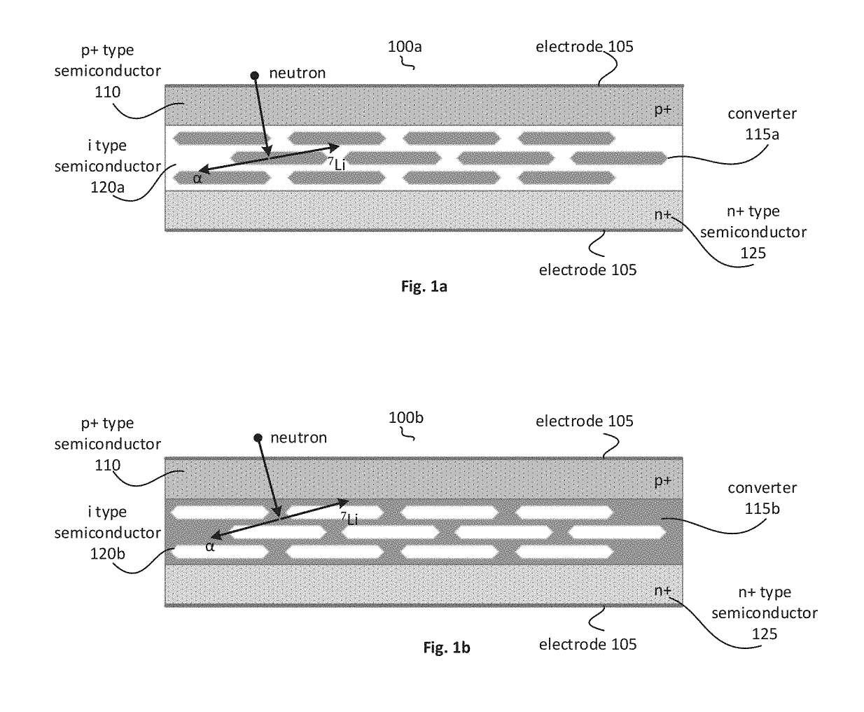

FIGS. 1a and 1b illustrate exemplary neutron detector configurations of the present invention wherein the detectors are fabricated comprising nanoflake/sheet nanostructures. In the exemplary neutron detector 100a embodiment of FIG. 1a layered nanoflakes 115a (e.g., boron nitride) are used as a neutron converter material and a solution-based semiconductor precursor (organic or inorganic material) is utilized as a matrix 120a. In this embodiment nanoflakes 115a are dispersed within an i-type semiconductor precursor solution 120a (e.g., cyclopentasilane oligomer for the fabrication of silicon) and thereafter the precursor is converted into a semiconductor by thermal liv treatment. Alternatively, in additional embodiments solution-based organic semiconductor matrix materials can be insinuated between the nanoflakes/sheets 115a.

The internal structure of the device 100a consists of an overlapping mosaic of neutron converter nanoflakes 115a with the spaces between the flakes 115a being filled with the semiconductor matrix 120a. The unique detector structure insures the presence of a sufficient amount of converter material necessitated to capture most of any incoming neutrons and semiconductor materials in order to maximize the efficiency of neutron detection. Further shown in FIG. 1a are p-type 110 and n-type 125 semiconducting material substrates that have been provided to complete the fabrication of the p-i-n diode detector 100a. Aluminum is sputtered onto the outer surfaces of the substrates 110 and 125 of the device 100a in order to fabricate the electrodes 105.

FIG. 1b illustrates a neutron detector that has been fabricated conversely from the detector of FIG. 1a. Within FIG. 1b the nanostructured nanoflakes/sheets 120b of the neutron detector 100b are fabricated from an i-type semiconductor material. As such, the i-type semiconductor nanoflakes 120b of FIG. 1b are dispersed within a matrix comprising a neutron converting material 115b. Electrodes 105 are provided to complete the fabrication of the device 100b.

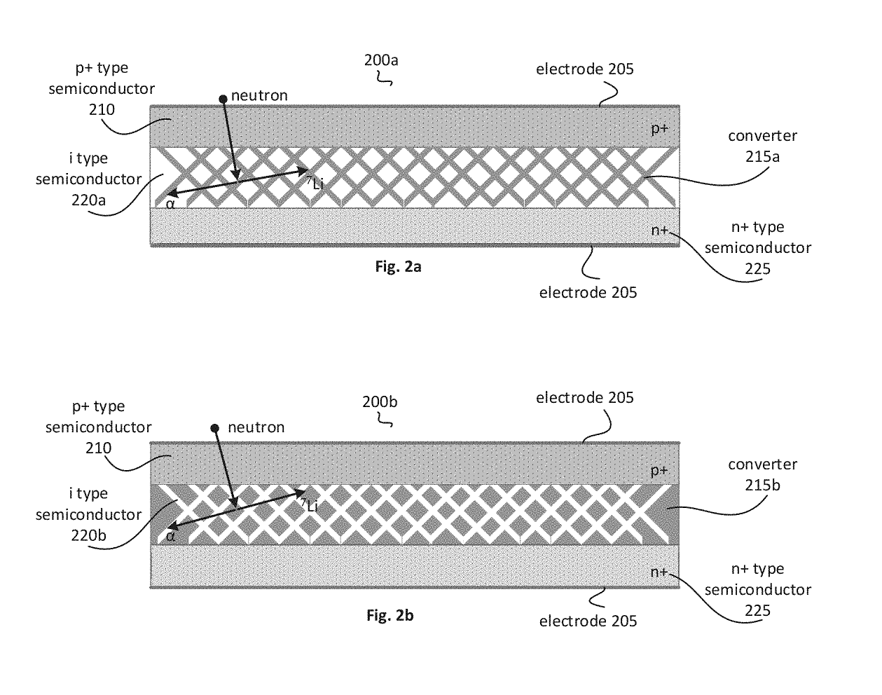

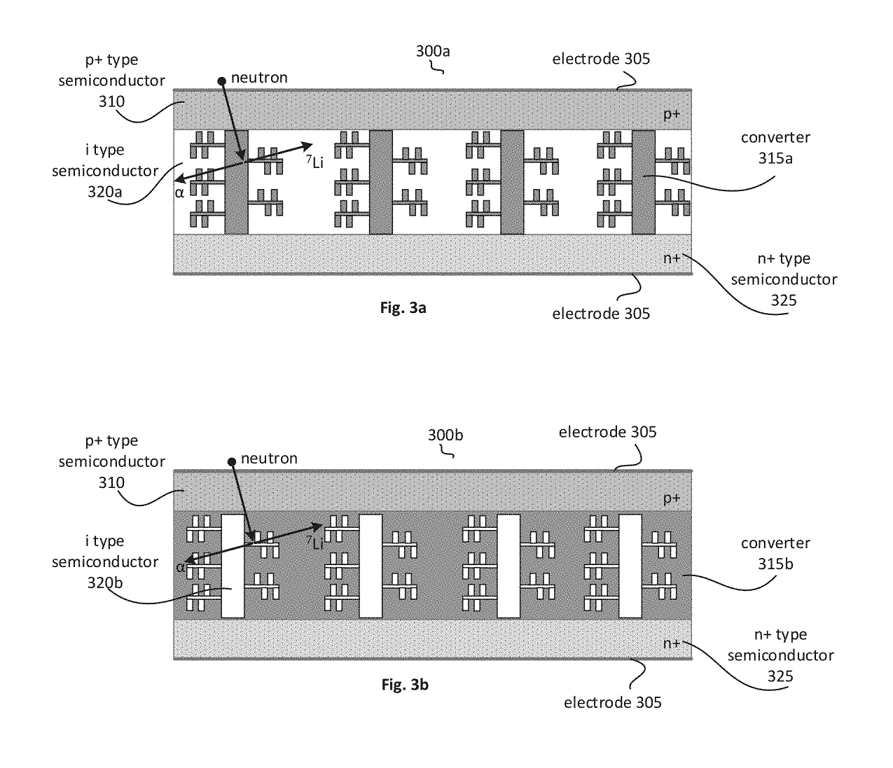

In the exemplary embodiments as illustrated in FIGS. 2a and 2b, 3D nanowire networks are utilized in order to increase the detection efficiency of the solid-state neutron detectors 200a and 200b. The use of 3D nanowire network materials (fabricated from semiconductor materials 220b (FIG. 2b) or converter materials 215a (FIG. 2a)) significantly increase the contact surface of the detector with neutrons, thus improving the detection efficiency of the device.

Within the exemplary embodiments of the present invention the 3D nanowire networks 215a, 220b can be synthesized by use of direct synthetic fabrication approaches such as hard templating methodologies, epitaxial growth, or vapor-liquid-solid processes. To complete the fabrication of the p-i-n diode detectors 200a and 200b, p-type 210 and n-type 225 semiconducting material substrates and electrodes 205 are provided.

The nanostructures of the embodiments of FIGS. 3a and 3b comprise nanowire trees that have been fabricated from a neutron converting material 315a (FIG. 3a) and a neutron detecting material 320b (FIG. 3b). The nano-trees 315a, 320b are vertically aligned in the matrix (the semiconductor material 320a of FIG. 3a or the converter material 315b of FIG. 3b) of their respective detector arrays. The network nanowire trees 315a, 320b comprised within the matrix 320a, 315b mimic the structure of a forest of trees, with individual vertical “trees” sprouting hundreds of nano-sized “branches”. The tree's 315a, 320b vertical structure and large number of branches are key to capturing a maximum number of incoming neutrons at the detectors 300a, 300b in order to maximize the detection efficiency of the neutron detectors 300a, 300b. As in the previous embodiments p-type 310 and n-type 325 semiconducting materials and electrodes 305 are provided to complete the fabrication of the p-i-n diode detectors 300a and 300b.

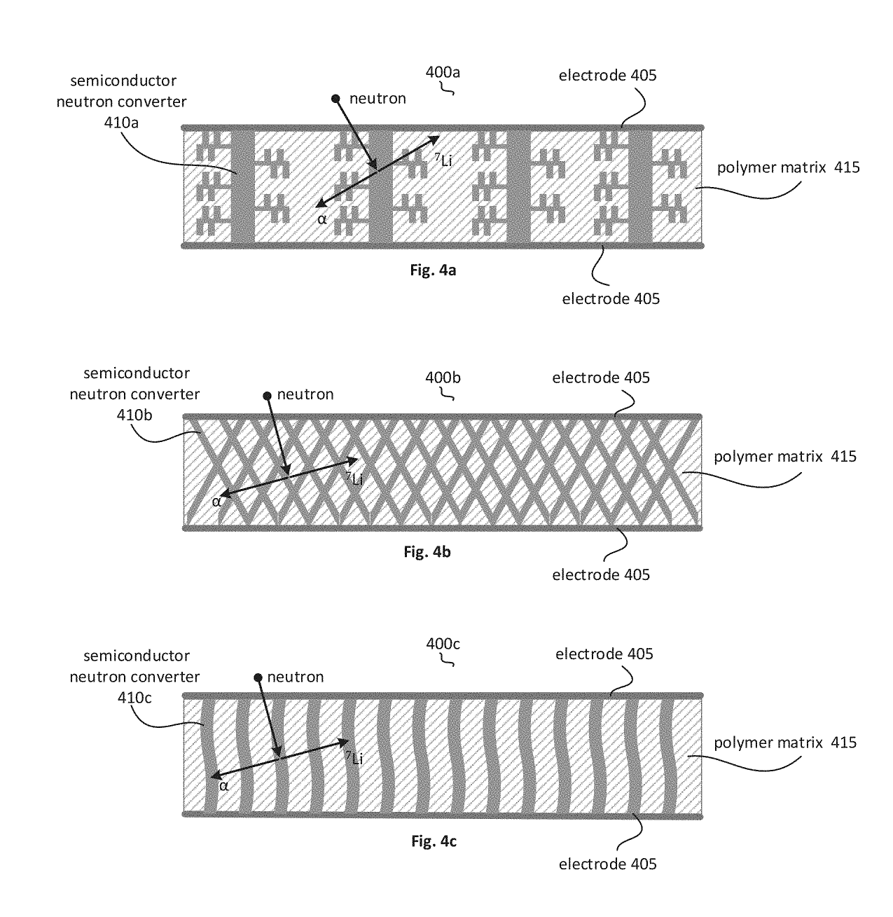

In the exemplary embodiments as shown in FIGS. 4a, 4b, and 4c, electrically conductive nanostructured materials (nano-trees 410a (FIG. 4a), nanowire network 410b (FIG. 4b), nanowire 410c (FIG. 4c)), containing high neutron cross sectional components (e.g. boron carbide semiconductors, boron gallium nitride semiconductors) are implemented both as neutron converter material and charge carrier material without the further use of any additional semiconducting materials.

If necessary, a predetermined amount of converter material can be deposited on the top of the detector composite (410a, 415) (410b, 415) (410c, 415) in order to enhance the conversion efficiency of colliding neutrons into alpha particles. Flexible organic matrix materials can be employed within further exemplary embodiments as a gap filling material that enables the fabrication of flexible neutron sensors that can be directly embedded within clothing fabric material. Electrodes 405 are provided in all illustrative embodiments to complete the fabrication of each respective neutron detector 400a, 400b, and 400c.

In summary, as described above and furthered claimed, exemplary embodiments of the present invention comprise high efficiency 3D nanostructured neutron detectors. The neutron detectors have primary and secondary substrates, where each substrate has an external and internal surface area. The respective substrates are fabricated from either an n-type semiconductor material or a p-type semiconductor material, Disposed between the primary and secondary substrates is a composite structure that consists of a predetermined neutron converting material and a predetermined neutron detecting material. In exemplary embodiments of the present invention one of the composite materials (either the neutron converting material or the neutron detecting material) is fabricated into a nanostructure in the configuration of a stack of nanosheets, a 3D nanowire network, or as 3D nano-trees. Lastly, a pair of electrodes is disposed on the respective external surface areas of the primary and secondary substrates.

The exemplary embodiments of the 3D nanostructure neutron detectors of the present invention comprise nanostructures that are fabricated from nanotubes or nanowires. The structural parameters of the nanostructure are predetermined in order to access and then control the fabrication dimensions of the nanostructured materials. Within exemplary embodiments of the present invention the identified nanostructures can be fabricated by the micro-architecture pattern growth of the nanostructures directly on a semiconductor substrate.

The exemplary 3D nanostructure embodiments of the present invention allow for the fabricated nanostructures to be constructed from a selection of neutron converting materials or neutron detecting materials. Once a material is selected in accordance with the exemplary embodiments of the present invention a plurality of nanosheets, 3D nanowire networks, or 3D nano-trees can be fabricated for usage in 3D neutron detectors.

As mentioned above, in a yet further exemplary embodiment of the present invention the 3D nanostructure neutron detector is fabricated entirely from a neutron conducting material. In this embodiment the 3D nanostnictures can comprise a plurality of neutron converting nanowires, 3D nano-trees, or 3D nanowire networks. The fabricated nanostructure can thereafter be dispersed within a structure comprised of a flexible organic matrix material.

This invention affords several advantages over current solid-state neutron detectors. First, 3D nanowire network array comprises a high density and high surface area of converter materials or detection materials. These properties insure enough converter materials are provided to sufficiently capture most of the incoming thermal neutrons arriving at a detector. Second, the invention features a high-aspect-ratio hierarchical structure of converter and detection materials that maximize detection efficiency of semiconductor matrix for most charged particles generated at different depth of the converter materials. Lastly, the employment of organic semiconductor matrix materials enables for the fabrication of a flexible neutron sensor that could be directly embedded in clothing; the flexible neutron sensor being configured to be stacked in a predetermined number of segments in order to provide a 3D neutron detector sensing system.

While the invention has been described with reference to exemplary embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiments disclosed for carrying out this invention, but that the invention will include all embodiments falling within the scope of the claims.

What is claimed:

1. A high efficiency 3D nanostructured neutron detector, the neutron detector comprising:
a primary and secondary substrate, each substrate comprising an external and internal surface area, wherein one of the respective substrates comprises an n-type semiconductor material and the other substrate comprises a p-type semiconductor material, and further, disposed between the primary and secondary substrates is:
a composite structure consisting of a predetermined neutron converting material and a predetermined neutron detecting material, wherein one of the composite materials is fabricated into a nanostructure in the configuration of a stack of nanosheets, a 3D nanowire network, or as 3D nano-trees; and
a pair of electrodes, wherein one electrode is disposed on the respective external surface areas of the primary and secondary substrates.

2. The 3D nanostructure neutron detector of claim 1, wherein the nanostructure is fabricated from nanotubes or nanowires.

3. The 3-D nanostructure neutron detector of claim 2, wherein the structural parameters of the nanostructure are determined in order to control the fabrication dimensions of the nanostructured materials.

4. The 3-D nanostructure neutron detector of claim 3, wherein nanostructures can be fabricated by micro-architectured pattern growth directly on a semiconductor substrate.

5. The 3D nanostructure neutron detector of claim 4, wherein the fabricated nanostructure comprises a predetermined neutron converting material.

5. The 3D nanostructure neutron detector of claim 5, wherein the structure of the composite comprises a plurality of neutron converting material nanosheets, 3D nanowire networks, or 3D nano-trees that have been dispersed within a structure comprised of a neutron detecting material.

7. The 3D nanostructure neutron detector of claim 4, wherein the fabricated nanostructure comprises a predetermined neutron detecting material.

8. The 3D nanostructure neutron detector of claim 7, wherein the structure of the composite comprises a plurality of neutron detecting material 3D nanowires or 3D nano-trees that have been dispersed within a structure comprised of a neutron converting material.

9. The 3D nanostructure neutron detector of claim 4, wherein the fabricated nanostructure comprises a predetermined neutron conducting material.

10. The 3D nanostructure neutron detector of claim 9, wherein the structure of the composite comprises a plurality of neutron converting nanowires, 3D nano-trees, or 3D nanowire networks dispersed within a structure comprised of a flexible organic matrix material.

11. A method for the fabrication of a high efficiency 3D nanostructured neutron detector, the method comprising the steps of:
fabricating a primary and secondary substrate, each comprising an outer and inner surface area, wherein one of the respective substrates comprises an n-type semiconductor material and the other substrate comprises a p-type semiconductor material;
fabricating upon the inner surface area of the primary substrate a composite structure, the composite structure consisting of a predetermined neutron converting material and a predetermined neutron detecting material wherein one of the composite materials is fabricated into a nanostructure, the nanostructure being fabricated into a nanostructure array in the configuration of a stack of nanosheets, a 3D nanowire network or as 3D nano-trees;
depositing the inner surface area of the secondary semiconducting substrate upon an exposed upper surface area of the composite structure; and
forming a conductive layer upon each substrate by depositing an electrode onto the exposed outer surface areas of the primary and secondary semiconducting substrates.

12. The method of claim 11, further comprising the step of fabricating the nanostructure from nanotubes or nanowires.

13. The method of claim 12, further comprising the step of determining the structural parameters of the nanostructure in order to control the fabrication dimensions of the nanostructured materials.

14. The method of claim 13, further comprising the step of fabricating the nanostructures from micro-architectured patterns growth directly on a semiconductor substrate.

15. The method of claim 14, wherein the fabricated nanostructure comprises a predetermined neutron converting material.

16. The method of claim 15, wherein the structure of the composite comprises a plurality of neutron converting material nanosheets, 3D nanowire networks, or 3D nano-trees that have been dispersed within a structure comprised of a neutron detecting material.

17. The method of claim 14, wherein the fabricated nanostructure comprises a predetermined neutron detecting material.

18. The method of claim 17, wherein the composite comprises a plurality of neutron detecting material 3D nanowires or 3D nano-trees that have been dispersed within a structure comprised of a neutron converting material.

19. The method of claim 14, wherein the fabricated nanostructure comprises a predetermined neutron conducting material.

20. The method of claim 19, wherein the composite comprises a plurality of neutron converting nanowires, 3D nano-trees, or 3D nanowire networks dispersed within a structure comprised of a flexible organic matrix material.
